(19) United States
(12) Patent Application Publication
(10) Pub. No.: US 2025/0180374 A1
(43) Pub. Date: Jun. 5, 2025

(54) DIAGNOSTIC METHOD AND DIAGNOSTIC SYSTEM OF MEMS SENSOR

(71) Applicant: Panasonic Intellectual Property Management Co., Ltd., Osaka (JP)

(72) Inventor: Takeshi MORI, Fukui (JP)

(73) Assignee: Panasonic Intellectual Property Management Co., Ltd., Osaka (JP)

(21) Appl. No.: 18/835,190

(22) PCT Filed: Jan. 13, 2023
(86) PCT No.: PCT/JP2023/000882

§ 371 Date: Aug. 1, 2024

(30) Foreign Application Priority Data
Feb. 2, 2022 (JP) 2022-015215

(51) Int. Cl. G01C 25/00; G01C 19/5776; G01P 21/00

(52) U.S. Cl. CPC G01C 25/00; G01C 19/5776; G01P 21/00

(57) ABSTRACT

A rewrite control step includes causing, in response to a rewrite instruction of the response coefficient from an external system, a storage to execute a rewrite process of rewriting the response coefficient from a first response coefficient to a second response coefficient. An update control step includes causing a circuit unit to execute an update process of updating the circuit unit from the first response coefficient to the second response coefficient. A generation control step includes, after the update control step, causing a digital circuit unit to execute a generation process of generating a test output signal according to a test input signal input to a MEMS element or an analog circuit unit. A determination step includes executing a determination process of determining whether or not the test output signal falls within an allowable range specified by the test input signal.

### TECHNICAL FIELD

The present disclosure generally relates to diagnostic methods of MEMS sensors and diagnostic systems of MEMS sensors. The present disclosure specifically relates to a diagnostic method of a MEMS sensor of diagnosing the MEMS sensor and a diagnostic system of the MEMS sensor used to diagnose the MEMS sensor.

### BACKGROUND ART

Patent Literature 1 describes an acceleration sensor (MEMS sensor) including: at least one micromechanical sensor element (MEMS element); an electronic evaluation unit; and a monitor. The at least one micromechanical sensor element picks up acceleration. The evaluation unit has a redundant signal path including a separate A/D converter for each of the at least one sensor element. The monitor monitors parameters relevant for the functionality of the at least one A/D converter.

### CITATION LIST

### Patent Literature

Patent Literature 1: JP 2015-515616 A

### SUMMARY OF INVENTION

It is an object of the present disclosure to provide a diagnostic method of a MEMS sensor and a diagnostic system of the MEMS sensor which are configured to verify whether or not a rewrite and an update of a response coefficient in a response function used by a MEMS sensor have been successful.

A diagnostic method of a MEMS sensor according to an aspect of the present disclosure is a method of diagnosing a MEMS sensor including a MEMS element, an analog circuit unit, an A/D converter, a digital circuit unit, and a storage. The MEMS element is configured to output a first analog signal according to a magnitude of stress which is externally applied. The analog circuit unit is configured to perform signal processing on the first analog signal output from the MEMS element to output a second analog signal after the signal processing. The A/D converter is configured to convert the second analog signal output from the analog circuit unit into a digital signal. The digital circuit unit is configured to generate, based on the digital signal output from the A/D converter, an output signal according to the magnitude of the stress to output the output signal to an external system. The storage is configured to store a response coefficient in a response function used by at least one circuit unit of the analog circuit unit or the digital circuit unit. The diagnostic method of the MEMS sensor includes a rewrite control step, an update control step, a generation control step, and a determination step. The rewrite control step includes causing, in response to a rewrite instruction of the response coefficient from the external system, the storage to execute a rewrite process of rewriting the response coefficient from a first response coefficient to a second response coefficient. The update control step includes causing the at least one circuit unit to execute an update process of updating the response coefficient from the first response coefficient to the second response coefficient. The generation control step includes, after the update control step, causing the digital circuit unit to execute a generation process of generating a test output signal according to a test input signal input to the MEMS element or the analog circuit unit, the test output signal being digital, the test input signal being analog. The determination step includes executing a determination process of determining whether or not the test output signal is included in an allowable range specified by the test input signal.

A diagnostic system of a MEMS sensor according to an aspect of the present disclosure is a system for diagnosing a MEMS sensor including a MEMS element, an analog circuit unit, an A/D converter, a digital circuit unit, and a storage. The MEMS element is configured to output a first analog signal according to a magnitude of stress which is externally applied. The analog circuit unit is configured to perform signal processing on the first analog signal output from the MEMS element to output a second analog signal after the signal processing. The A/D converter is configured to convert the second analog signal output from the analog circuit unit into a digital signal. The digital circuit unit is configured to generate, based on the digital signal output from the A/D converter, an output signal according to the magnitude of the stress to output the output signal to an external system. The storage is configured to store a response coefficient in a response function used by at least one circuit unit of the analog circuit unit or the digital circuit unit. The diagnostic system of the MEMS sensor includes a rewrite controller, an update control unit, a generation controller, and a determination unit. The rewrite controller is configured to, in response to a rewrite instruction of the response coefficient from the external system, cause the storage to execute a rewrite process of rewriting the response coefficient from a first response coefficient to a second response coefficient. The update control unit is configured to cause the at least one circuit unit to execute an update process of updating the response coefficient from the first response coefficient to the second response coefficient. The generation controller is configured to, after the update control unit causes the at least one circuit unit to execute the update process, cause the digital circuit unit to execute a generation process of generating a test output signal according to a test input signal input to the MEMS element or the analog circuit unit, the test output signal being digital, the test input signal being analog. The determination unit is configured to execute a determination process of determining whether or not the test output signal is included in an allowable range specified by the test input signal.

### BRIEF DESCRIPTION OF DRAWINGS

FIG. 1 is a flowchart of a diagnostic method of a MEMS sensor according to an embodiment;

FIG. 2 is a block diagram of a diagnostic system of the MEMS sensor according to the embodiment;

FIG. 3 is a frequency characteristic diagram of a low-pass filter used in the MEMS sensor;

FIG. 4 is a frequency characteristic diagram of a high-pass filter used in a MEMS sensor according to a first variation of the embodiment;

FIG. 5 is a block diagram of a diagnostic system of a MEMS sensor according to a second variation of the embodiment; and

FIG. 6 is a flowchart of a diagnostic method of the MEMS sensor according to the second variation of the embodiment.

### DESCRIPTION OF EMBODIMENTS

### Embodiment

A diagnostic method of a MEMS sensor and a diagnostic system of the MEMS sensor according to an embodiment will be described below with reference to the drawings. The drawings to be referred to in the following description of the embodiment are all schematic representations. Thus, the ratio of the dimensions (including thicknesses) of respective constituent elements illustrated on the drawings does not always reflect their actual dimensional ratio. Moreover, configurations described in the embodiment below are mere examples of the present disclosure. The present disclosure is not limited to the embodiment described below and may be modified in various manners depending on design or the like as long as the effect of the present disclosure is produced.

### (1) Overview

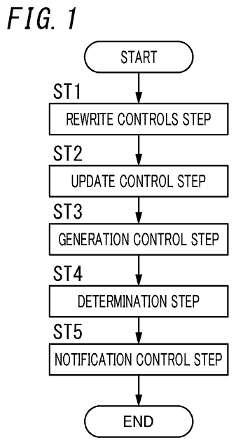

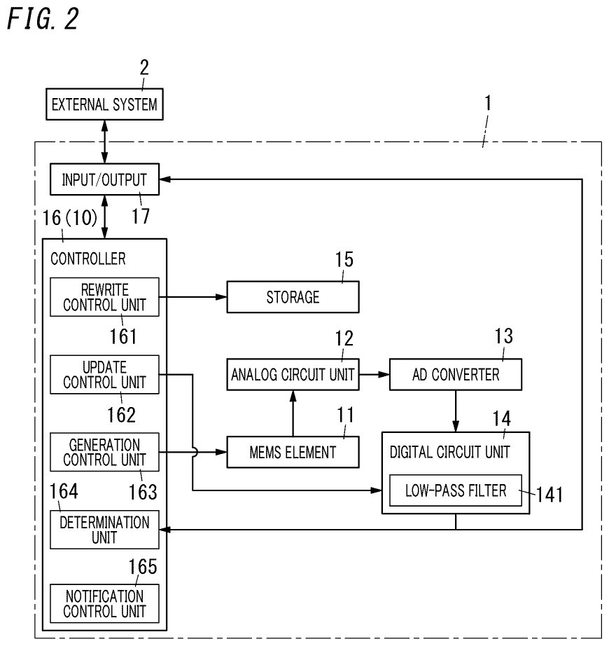

First of all, the overview of a diagnostic method of a MEMS sensor 1 and a diagnostic system 10 of the MEMS sensor 1 according to the embodiment will be described with reference to FIGS. 1 and 2.

The diagnostic method of the MEMS sensor 1 according to the embodiment is a method of diagnosing the MEMS sensor 1. The micro electro mechanical systems (MEMS) sensor 1 is, for example, a gyroscope sensor (angular velocity sensor). In the present embodiment, as an example, the MEMS sensor 1 is assumed to be a single axis vibrating structure gyroscope sensor. The MEMS sensor 1 is not limited to a gyroscope sensor but may be, for example, an acceleration sensor.

Incidentally, the MEMS sensor 1 includes an analog circuit unit 12 and a digital circuit unit 14 as described later. At least one circuit unit of the analog circuit unit 12 or the digital circuit unit 14 uses a response function. The at least one circuit unit updates a response coefficient in the response function to output a signal according to the response coefficient thus updated. Therefore, when the response coefficient has not been updated, a signal according to the response coefficient before the update is output. Thus, in the field of MEMS sensors 1, a system is in demand which is configured to verify whether or not an update of the response coefficient has been successful. The diagnostic method of the MEMS sensor 1 according to the embodiment has the following configuration to achieve the object.

That is, the diagnostic method of the MEMS sensor 1 according to the embodiment is a method of diagnosing the MEMS sensor 1 including a MEMS element 11, the analog circuit unit 12, an A/D converter 13, the digital circuit unit 14, and a storage 15. The MEMS element 11 outputs a first analog signal according to the magnitude of stress which is externally applied. The analog circuit unit 12 performs signal processing on the first analog signal output from the MEMS element 11 to output a second analog signal after the signal processing. The A/D converter 13 converts the second analog signal output from the analog circuit unit 12 into a digital signal. The digital circuit unit 14 generates, based on the digital signal output from the A/D converter 13, an output signal according to the magnitude of the stress to output the output signal to an external system 2. The storage 15 stores the response coefficient in the response function used by the at least one circuit unit of the analog circuit unit 12 or the digital circuit unit 14. As shown in FIG. 1, the diagnostic method of the MEMS sensor 1 includes a rewrite control step ST1, an update control step ST2, a generation control step ST3, and a determination step ST4. The rewrite control step ST1 includes causing, in response to a rewrite instruction of the response coefficient from the external system 2, the storage 15 to execute a rewrite process of rewriting the response coefficient from a first response coefficient to a second response coefficient. The update control step ST2 includes causing the at least one circuit unit to execute an update process of updating the response coefficient from the first response coefficient to the second response coefficient. The generation control step ST3 includes, after the update control step ST2, causing the digital circuit unit 14 to execute a generation process of generating a test output signal according to a test input signal input to the MEMS element 11 or the analog circuit unit 12, the test output signal being digital, the test input signal being analog. The determination step ST4 includes executing a determination process of determining whether or not the test output signal is included in an allowable range specified by the test input signal.

Thus, the diagnostic method of the MEMS sensor 1 according to the embodiment determines, in the determination step ST4, whether or not the test output signal is included in the allowable range specified by the test input signal. Therefore, if the test output signal is included in the allowable range, it can be determined that a rewrite and an update of the response coefficient have been successful, and if the test output signal is not included in the allowable range, it can be determined that the rewrite and the update of the response coefficient have failed. That is, the diagnostic method of the MEMS sensor 1 according to the embodiment enables verification of whether or not the rewrite and the update of the response coefficient in the response function used by the MEMS sensor 1 have been successful.

Moreover, the diagnostic method of the MEMS sensor 1 according to the embodiment may be implemented by, for example, the diagnostic system 10 of the MEMS sensor 1 as shown in FIG. 2. That is, the diagnostic system 10 of the MEMS sensor 1 is an aspect for implementing the diagnostic method of the MEMS sensor 1 described above. The diagnostic system 10 of the MEMS sensor 1 according to the embodiment is a system for diagnosing the MEMS sensor 1 including the MEMS element 11, the analog circuit unit 12, the A/D converter 13, the digital circuit unit 14, and the storage 15. As shown in FIG. 2, the diagnostic system 10 of the MEMS sensor 1 includes a rewrite controller 161, an update control unit 162, a generation controller 163, and a determination unit 164. The rewrite controller 161 causes, in response to the rewrite instruction of the response coefficient from the external system 2, the storage 15 to execute the rewrite process of rewriting the response coefficient from the first response coefficient to the second response coefficient. The update control unit 162 causes the at least one circuit unit to execute the update process of updating the response coefficient from the first response coefficient to the second response coefficient. After the update control unit 162 causes the at least one circuit unit to execute the update process, the generation controller 163 causes the digital circuit unit 14 to execute the generation process of generating the test output signal according to the test input signal input to the MEMS element 11 or the analog circuit unit 12, the test output signal being digital, the test input signal being analog. The determination unit 164 executes the determination process of determining whether or not the test output signal is included in the allowable range specified by the test input signal.

### (2) Details

Next, details of the diagnostic system 10 of the MEMS sensor 1 according to the embodiment will be described with reference to FIG. 2.

As shown in FIG. 2, the MEMS sensor 1 according to the embodiment includes the MEMS element 11, the analog circuit unit 12, the A/D converter 13, the digital circuit unit 14, the storage 15, a controller 16, and an input/output 17. In the present embodiment, the controller 16 of the MEMS sensor 1 functions as the diagnostic system 10 of the MEMS sensor 1. That is, the diagnostic system 10 of the MEMS sensor 1 according to the embodiment is integrated with the MEMS sensor 1. In other words, the rewrite controller 161, the update control unit 162, the generation controller 163, and the determination unit 164 which will be described later are integrated with the MEMS sensor 1. In the present embodiment, the analog circuit unit 12, the A/D converter 13, the digital circuit unit 14, the storage 15, the controller 16, and the input/output 17 are configured as a single application specific integrated circuit (ASIC). Note that the analog circuit unit 12, the A/D converter 13, the digital circuit unit 14, the storage 15, the controller 16, and the input/output 17 are not limited to the single ASIC but may be configured as, for example, one or more integrated circuits (IC) or a microcomputer.

### (2.1) MEMS Element

The MEMS element 11 is, for example, an angular velocity detection element configured to detect an angular velocity around the Z-axis of X-, Y-, and Z-axes orthogonal to each other. The MEMS element 11 includes, for example, a vibrator and a detection electrode. The vibrator vibrates (is displaced), for example, in an X-axis direction. The detection electrode detects, from electrostatic capacitance generated between the detection electrode and the vibrator, displacement of the vibrator in a Y-axis direction according to the Coriolis force. That is, the MEMS sensor 1 is a capacitive gyroscope sensor. The MEMS element 11 outputs a first analog signal (voltage signal) according to the magnitude of stress which is externally applied. In other words, the MEMS element 11 outputs the first analog signal according to the Coriolis force generated at the MEMS element 11.

Note that the configuration of the MEMS element 11 is not limited to the configuration described above, but the MEMS element 11 may have another configuration as long as the angular velocity around the Z-axis is detectable. Moreover, the MEMS sensor 1 is not limited to being capacitive but may be, for example, piezoelectric.

### (2.2) Analog Circuit Unit

The analog circuit unit 12 has an input terminal connected to an output terminal of the MEMS element 11. The analog circuit unit 12 receives the first analog signal output from the MEMS element 11. The analog circuit unit 12 performs the signal processing on the first analog signal from the MEMS element 11. Specifically, the analog circuit unit 12 performs coherent detection on the first analog signal from the MEMS element 11 to extract, from the first analog signal, a component signal corresponding to the Coriolis force. Here, in the present embodiment, the component signal corresponds to the second analog signal. That is, the analog circuit unit 12 performs the signal processing on the first analog signal output from the MEMS element 11 to output the second analog signal after the signal processing.

### (2.3) A/D Converter

The analog-to-digital (A/D) converter 13 has an input terminal connected to an output terminal of the analog circuit unit 12. The A/D converter 13 receives the second analog signal output from the analog circuit unit 12. The A/D converter 13 converts the second analog signal into a digital signal and outputs the digital signal to the digital circuit unit 14.

### (2.4) Digital Circuit Unit

The digital circuit unit 14 has an input terminal connected to an output terminal of the A/D converter 13. The digital circuit unit 14 receives the digital signal output from the A/D converter 13. The digital circuit unit 14 outputs, based on the digital signal output from the A/D converter 13, an output signal (angular velocity signal) according to the magnitude of the stress applied to the MEMS element 11 to the external system 2.

Specifically, the digital circuit unit 14 includes a low-pass filter (LPF) 141 as shown in FIG. 2. The low-pass filter 141 is, for example, a digital filter. The digital circuit unit 14 uses the low-pass filter 141 to remove or reduce components of a second frequency range, in which frequencies are higher than in a first frequency range, from or in the digital signal output from the A/D converter 13, thereby extracting a signal of the first frequency range. Moreover, the digital circuit unit 14 performs a gain adjustment and/or an offset adjustment of the signal thus extracted and further executes a compensation process (e.g., a temperature compensation process) to calculate, for example, an average value per unit time of the angular velocity. Then, the digital circuit unit 14 generates an angular velocity signal (output signal) including the average value per unit time of the angular velocity and outputs the angular velocity signal to the external system 2.

In the present embodiment, the digital circuit unit 14 which is one of the analog circuit unit 12 and the digital circuit unit 14 has the response function. The response function is, for example, a transfer function of the low-pass filter 141. Moreover, the response coefficient in the response function is, for example, a gain of the low-pass filter 141.

### (2.5) Storage

The storage 15 includes nonvolatile memory such as flash memory. The storage 15 stores the response coefficient in the response function used by the digital circuit unit 14. More specifically, the storage 15 stores a look up table as shown in Table 1. In Table 1, a low-pass filter and a high-pass filter are shown as examples of filters used in the digital circuit unit 14.

TABLE 1

| Types of Filters | Cutoff Frequency (Hz) | Gain (dB) |
|---|---|---|
| LPF | 10 | −6.5 |
| | 30 | −0.6 |
| | 60 | 0 |
| HPF | 10 | 0 |
| | 30 | −9.0 |
| | 60 | −35.0 |

### (2.6) Controller

As described above, the controller 16 functions as the diagnostic system 10 of the MEMS sensor 1 according to the embodiment.

As shown in FIG. 2, the controller 16 includes the rewrite controller 161, the update control unit 162, the generation controller 163, the determination unit 164, and a notification controller 165. In other words, the diagnostic system 10 of the MEMS sensor 1 includes the rewrite controller 161, the update control unit 162, the generation controller 163, the determination unit 164, and the notification controller 165.

The rewrite controller 161 causes, in response to the rewrite instruction from the external system 2, the storage 15 to execute the rewrite process. The rewrite process is a process of rewriting the response coefficient from the first response coefficient to the second response coefficient. That is, the storage 15 rewrites, in response to a control instruction from the rewrite controller 161, the response coefficient from the first response coefficient to the second response coefficient in the rewrite process.

The update control unit 162 causes the at least one circuit unit of the analog circuit unit 12 or the digital circuit unit 14 to execute the update process. The update process is a process of updating the response coefficient from the first response coefficient to the second response coefficient. That is, the at least one circuit unit updates, in response to a control instruction from the update control unit 162, the response coefficient from the first response coefficient to the second response coefficient. In the present embodiment, the at least one circuit unit is the digital circuit unit 14.

After the update control unit 162 causes the digital circuit unit 14 to execute the update process, the generation controller 163 causes the digital circuit unit 14 to execute the generation process. The generation process is a process of generating a test output signal according to a test input signal input to the MEMS element 11. The test input signal is a signal input to the MEMS element 11 and is an analog signal. More specifically, the test input signal is an alternating current signal (AC signal) according to the magnitude of test stress to the MEMS element 11. The test output signal is a digital signal output from the digital circuit unit 14.

The determination unit 164 executes the determination process. The determination process is a process of determining whether or not the test output signal is included in the allowable range. The allowable range of the test output signal is specified by the test input signal. Moreover, the determination unit 164 determines, in the determination process, that the rewrite and the update of the response coefficient have been successful if the test output signal is included in the allowable range and that the rewrite and the update of the response coefficient have failed if the test output signal is not included in the allowable range.

If the determination unit 164 determines that the test output signal falls out of the allowable range, the notification controller 165 causes the external system 2 to execute the notification process. The notification process is a process of notifying that an error has occurred in the rewrite control step ST1 or the update control step ST2 which will be described later. That is, the external system 2 notifies, in response to a control instruction from the notification controller 165, that the error has occurred in the rewrite control step ST1 or the update control step ST2. A notification method may be, for example, when the external system 2 includes a display unit, displaying a notification content on the display unit, or when the external system 2 includes a loudspeaker, notifying of the notification content by voice. Thus, a user of the MEMS sensor 1 can know that the error has occurred in the rewrite control step ST1 or the update control step ST2 and the rewrite or the update of the response coefficient has thus failed.

### (2.7) Input/Output

The input/output 17 includes an input/output interface between the input/output 17 and the external system 2. The input/output 17 inputs, for example, the rewrite instruction from the external system 2 to the controller 16 (diagnostic system 10). Moreover, the input/output 17 outputs the output signal (angular velocity signal) from the digital circuit unit 14, a determination result by the determination unit 164, the control instruction from the notification controller 165, and the like to the external system 2.

### (3) Diagnostic Method of MEMS Sensor

Next, the diagnostic method of the MEMS sensor 1 will be described with reference to FIGS. 1 and 2.

The diagnostic method of the MEMS sensor 1 according to the embodiment is a method of diagnosing the MEMS sensor 1 including the MEMS element 11, the analog circuit unit 12, the A/D converter 13, the digital circuit unit 14, and the storage 15. The MEMS element 11 outputs a first analog signal according to the magnitude of stress which is externally applied. The analog circuit unit 12 performs signal processing on the first analog signal output from the MEMS element 11 to output a second analog signal after the signal processing. The A/D converter 13 converts the second analog signal output from the analog circuit unit 12 into a digital signal. The digital circuit unit 14 generates, based on the digital signal output from the A/D converter 13, an output signal according to the magnitude of the stress to output the output signal to the external system 2. The storage 15 stores the response coefficient in the response function used by at least of the analog circuit unit 12 or the digital circuit unit 14. The diagnostic method of the MEMS sensor 1 includes the rewrite control step ST1, the update control step ST2, the generation control step ST3, and the determination step ST4. The rewrite control step ST1 includes causing, in response to a rewrite instruction of the response coefficient from the external system 2, the storage 15 to execute a rewrite process of rewriting the response coefficient from a first response coefficient to a second response coefficient. The update control step ST2 includes causing the at least one circuit unit (in the present embodiment, the digital circuit unit 14) to execute an update process of updating the response coefficient from the first response coefficient to the second response coefficient. The generation control step ST3 includes, after the update control step ST2, causing the digital circuit unit 14 to execute a generation process of generating a test output signal according to a test input signal input to the MEMS element 11 or the analog circuit unit 12. The determination step ST4 includes executing a determination process of determining whether or not the test output signal falls within an allowable range specified by the test input signal.

The diagnostic method of the MEMS sensor 1 according to the embodiment determines, in the determination step ST4, whether or not the test output signal falls within the allowable range specified by the test input signal. Therefore, if the test output signal falls within the allowable range, it can be determined that a rewrite and an update of the response coefficient have been successful, and if the test output signal falls out of the allowable range, it can be determined that the rewrite or the update of the response coefficient has failed. That is, the diagnostic method of the MEMS sensor 1 according to the embodiment enables verification of whether or not the rewrite and the update of the response coefficient in the response function used by the MEMS sensor 1 have been successful.

Moreover, the diagnostic method of the MEMS sensor 1 according to the embodiment further includes a notification control step ST5. The notification control step ST5 includes causing the external system 2 to execute a notification process of notifying that an error has occurred in the rewrite control step ST1 or the update control step ST2 if the test output signal is determined not to be included in the allowable range in the determination step ST4. This can notify a user of the MEMS sensor 1 that the error has occurred in the rewrite control step ST1 or the update control step ST2 and the rewrite or the update of the response coefficient has thus failed.

FIG. 1 is a flowchart of the diagnostic method of the MEMS sensor 1 according to the embodiment. The diagnostic method of the MEMS sensor 1 includes steps ST1 to ST5 shown in FIG. 1. Note that the flowchart shown in FIG. 1 is a mere example, and the order of the steps may accordingly be changed, or a step(s) may be omitted.

First of all, the diagnostic system 10 of the MEMS sensor 1 executes the rewrite control step ST1. In the rewrite control step ST1, the rewrite controller 161 causes, in response to the rewrite instruction from the external system 2, the storage 15 to execute the rewrite process of rewriting the response coefficient stored in the storage 15 from the first response coefficient to the second response coefficient. That is, the storage 15 rewrites, in response to the control instruction from the rewrite controller 161, the response coefficient from the first response coefficient to the second response coefficient.

Next, the diagnostic system 10 of the MEMS sensor 1 executes the update control step ST2. In the update control step ST2, the update control unit 162 causes the circuit unit (in this embodiment, the digital circuit unit 14) to execute the update process of updating the response coefficient in the response function used by the circuit unit from the first response coefficient to the second response coefficient. That is, the circuit unit updates, in response to the control instruction from the update control unit 162, the response coefficient from the first response coefficient to the second response coefficient.

Then, the diagnostic system 10 of the MEMS sensor 1 executes the generation control step ST3 after the update control step ST2. In the generation control step ST3, the generation controller 163 inputs a test input signal including an analog signal to the MEMS sensor 1 to cause the digital circuit unit 14 to generate a test output signal including a digital signal. That is, the digital circuit unit 14 generates, in the generation process, the test output signal according to the test input signal input to the MEMS sensor 1 from the generation controller 163.

Next, the diagnostic system 10 of the MEMS sensor 1 executes the determination step ST4. In the determination step ST4, the determination unit 164 executes the determination process of determining whether or not the test output signal from the digital circuit unit 14 is included in the allowable range. Then, the determination unit 164 determines that the rewrite and the update of the response coefficient have been successful if the test output signal is included in the allowable range and that the rewrite or the update of the response coefficient has failed if the test output signal is not included in the allowable range.

Finally, if the test output signal is determined not to be included in the allowable range in the determination step ST4, the diagnostic system 10 of the MEMS sensor 1 executes the notification control step ST5. In the notification control step ST5, the notification controller 165 causes the external system 2 to execute the notification process of notifying that an error has occurred in the rewrite control step ST1 or the update control step ST2, that is, the rewrite or the update of the response coefficient has failed. That is, the external system 2 executes the notification process described above in response to the control instruction from the notification controller 165.

Here, in the diagnostic method of the MEMS sensor 1 according to the embodiment, the above-described rewrite control step ST1, update control step ST2, generation control step ST3, and determination step ST4 are executed upon activation of the MEMS sensor 1. Since no external stress is being applied to the MEMS sensor 1 at the time of the activation of the MEMS sensor 1, wrong diagnoses due to actual stress applied to the MEMS sensor 1 can be reduced.

### (4) Details of Determination Step

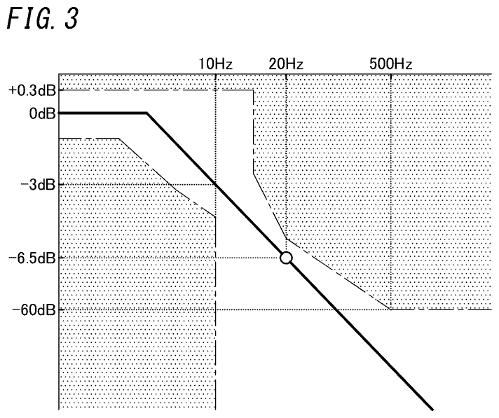

Next, the details of the determination step ST4 will be described with reference to FIG. 3. FIG. 3 is a frequency characteristic diagram of the low-pass filter 141 included in the digital circuit unit 14. In FIG. 3, the abscissa represents the frequency, and the ordinate in FIG. 3 represents the gain. Moreover, in FIG. 3, the cut frequency of the low-pass filter 141 is 10 Hz. Further, in FIG. 3, portions except for the allowable range of the test output signal specified by the test input signal are shaded with dots. That is, the allowable range is a portion not shaded with dots in FIG. 3.

In the determination step ST4, the determination unit 164 performs a process, such as the Fourier transform, on the test output signal output from the digital circuit unit 14, thereby obtaining the frequency characteristics of the low-pass filter 141 (see FIG. 3). According to FIG. 3, the gain of the low-pass filter 141 is included in the allowable range. For example, when the frequency of the test output signal is 20 Hz, the gain of the low-pass filter 141 is −6.5 dB. Similarly, according to the look up table (see Table 1) stored in the storage 15, the low-pass filter 141 having a cutoff frequency of 10 Hz has a gain of −6.5 dB when the frequency of the test output signal is 20 Hz. Since the two results are consistent, the determination unit 164 determines that the rewrite and the update of the response coefficient (gain) of the low-pass filter 141 have been successful. Moreover, if the two results are not consistent, the determination unit 164 determines that the rewrite or and the update of the response coefficient of the low-pass filter 141 has failed. As used in the present disclosure, “A and B are consistent” includes not only the case where A and B are exactly the same but also the case where B is included in a predetermined range including A.

Thus, the diagnostic method of the MEMS sensor 1 and the diagnostic system 10 of the MEMS sensor 1 according to the embodiment enable verification of whether or not the rewrite and the update of the response coefficient in the response function used by the MEMS sensor 1 have been successful.

### (5) Effects

The diagnostic method of the MEMS sensor 1 according to the embodiment determines, in the determination step ST4, whether or not the test output signal falls within the allowable range specified by the test input signal. Therefore, if the test output signal falls within the allowable range, it can be determined that the rewrite and the update of the response coefficient have been successful, and if the test output signal falls out of the allowable range, it can be determined that the rewrite or the update of the response coefficient has failed. That is, the diagnostic method of the MEMS sensor 1 according to the embodiment enables verification of whether or not the rewrite and the update of the response coefficient in the response function used by the MEMS sensor 1 have been successful.

Moreover, the diagnostic method of the MEMS sensor 1 according to the embodiment further includes the notification control step ST5. This enables the external system 2 to notify that an error has occurred in the rewrite control step ST1 or the update control step ST2.

Moreover, in the diagnostic method of the MEMS sensor 1 according to the embodiment, the rewrite control step ST1, the update control step ST2, the generation control step ST3, and the determination step ST4 are executed upon activation of the MEMS sensor 1. Thus, wrong diagnoses due to actual stress externally applied to the MEMS sensor 1 can be reduced.

Moreover, in the diagnostic method of the MEMS sensor 1 according to the embodiment, the test input signal is an alternating current signal according to the magnitude of the test stress to the MEMS element 11. Thus, simply inputting an alternating current signal to the MEMS element 11 or the analog circuit unit 12 enables verification of whether or not the rewrite and the update of the response coefficient in the response function used by the MEMS sensor 1 have been successful

### (6) Variations

The embodiment described above is merely an example of various embodiments of the present disclosure. The embodiment described above may be modified variously depending on design or the like as long as the object of the present disclosure is achieved. Moreover, functions similar to the diagnostic method of the MEMS sensor 1 according to the embodiment described above may be implemented by the diagnostic system 10 of the MEMS sensor 1, a (computer) program, or a non-transitory recording medium storing the program, for example.

Variations of the embodiment described above will be enumerated below. Any of the variations to be described below may be combined as appropriate.

### (6.1) First Variation

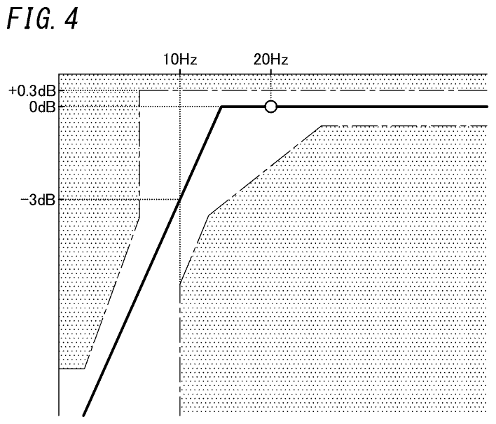

A diagnostic system of a MEMS sensor 1 according to a first variation is different from the diagnostic system 10 of the MEMS sensor 1 according to the embodiment described above in that the filter used in the digital circuit unit 14 is a high-pass filter. The diagnostic system of the MEMS sensor 1 and a diagnostic method of the MEMS sensor 1 according to the first variation will be described below with reference to FIG. 4. Note that in the diagnostic system of the MEMS sensor 1 according to the first variation, constituent elements similar to those in the diagnostic system 10 of the MEMS sensor 1 according to the embodiment described above are denoted by the same reference signs as those in the embodiment, and the description thereof is omitted. Moreover, in the diagnostic method of the MEMS sensor 1 according to the first variation, constituent elements similar to those in the diagnostic method of the MEMS sensor 1 according to the embodiment described above are denoted by the same reference signs as those in the embodiment, and the description thereof is omitted.

The diagnostic system of the MEMS sensor 1 according to the first variation executes the above-described rewrite control step ST1, update control step ST2, generation control step ST3, determination step ST4, and notification control step ST5 in this order. The diagnostic system of the MEMS sensor 1 determines, in the determination step ST4, whether or not a test output signal from the digital circuit unit 14 is included in an allowable range.

Here, FIG. 4 is a frequency characteristic diagram of the high-pass filter used in the digital circuit unit 14. In FIG. 4, the abscissa represents the frequency, and the ordinate in FIG. 4 represents the gain. Moreover, in FIG. 4, the cut frequency of the high-pass filter is 10 Hz. Further, in FIG. 4, portions except for the allowable range specified by a test input signal are shaded with dots. That is, the allowable range is a portion not shaded with dots in FIG. 4.

In the determination step ST4, the determination unit 164 performs a process, such as the Fourier transform, on the test output signal output from the digital circuit unit 14, thereby obtaining the frequency characteristics of the high-pass filter (see FIG. 4). According to FIG. 4, the gain of the high-pass filter is included in the allowable range. For example, when the frequency of the test output signal is 20 Hz, the gain of the high-pass filter is 0 dB. Similarly, according to the look up table (see Table 1) stored in the storage 15, the high-pass filter having a cutoff frequency of 10 Hz has a gain of 0 dB when the frequency of the test output signal is 20 Hz. Since the two results are consistent, the determination unit 164 determines that the rewrite and the update of the response coefficient (gain) of the high-pass filter have been successful. Moreover, if the two results are not consistent, the determination unit 164 determines that the rewrite or and the update of the response coefficient of the high-pass filter has failed.

Thus, the diagnostic method of the MEMS sensor 1 and the diagnostic system of the MEMS sensor 1 according to the first variation enable verification of whether or not the rewrite and the update of the response coefficient in the response function used by the MEMS sensor 1 have been successful

### (6.2) Second Variation

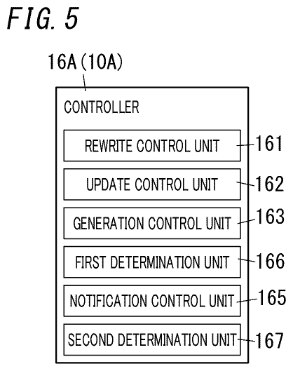

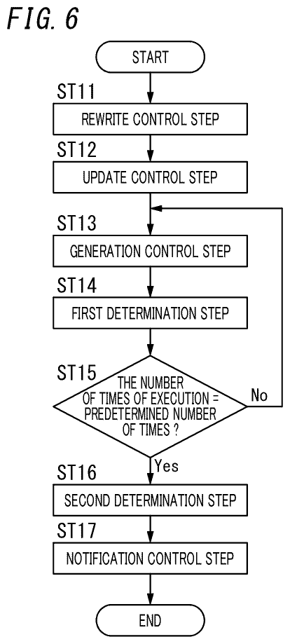

A diagnostic method of a MEMS sensor 1 according to a second variation is different from the diagnostic method of the MEMS sensor 1 according to the embodiment described above in that the diagnostic method of the second variation includes two determination steps (the first determination step ST14 and a second determination step ST16). The diagnostic method of the MEMS sensor 1 and a diagnostic system 10A of the MEMS sensor 1 according to the second variation will be described below with reference to FIGS. 5 and 6. Note that in the diagnostic system 10A of the MEMS sensor 1 according to the second variation, constituent elements similar to those in the diagnostic system 10 of the MEMS sensor 1 according to the embodiment described above are denoted by the same reference signs as those in the embodiment, and the description thereof will be omitted.

### (6.2 1) Diagnostic System

First of all, the diagnostic system 10A of the MEMS sensor 1 according to the second variation will be described with reference to FIG. 5.

The diagnostic system 10A of the MEMS sensor 1 according to the second variation includes a rewrite controller 161, an update control unit 162, a generation controller 163, a notification controller 165, a first determination unit 166, and a second determination unit 167 as shown in FIG. 5. The first determination unit 166 corresponds to the determination unit 164 of the diagnostic system 10 of the MEMS sensor 1 according to the embodiment described above. That is, the first determination unit 166 executes a first determination process of determining whether or not a test output signal from the digital circuit unit 14 (see FIG. 2) is included in an allowable range specified by a test input signal, the test output signal being digital, the test input signal being analog.

At a time when the rewrite controller 161 causes the storage 15 to execute the rewrite process once and the update control unit 162 causes the circuit unit (in this variation, the digital circuit unit 14) to execute the update process once, the generation controller 163 outputs a plurality of (e.g., three) test input signals to the MEMS sensor 1.

The first determination unit 166 executes the first determination process on each of a plurality of test output signals output from the digital circuit unit 14 (see FIG. 2) in response to the plurality of test input signals. That is, at a time when the rewrite controller 161 causes the storage 15 to execute the rewrite process once and the update control unit 162 causes the circuit unit to execute the update process once, the first determination unit 166 executes the first determination process a plurality of number of times (in this variation, three times).

The second determination unit 167 executes a second determination process in accordance with a determination result by the first determination unit 166. The second determination process is a process of determining whether or not the number of times the test output signal is included in the allowable range is greater than or equal to a specified number of times. In the second determination process, if the number of times the test output signal is included in the allowable range is greater than or equal to the specified number of times, the second determination unit 167 determines that the rewrite and the update of the response coefficient have been successful, and if the number of times the test output signal falls within the allowable range is less than the specified number of times, the second determination unit 167 determines that the rewrite or the update of the response coefficient has failed. Here, when the number of times the first determination process is executed is three times as in the case of the present variation, the specified number of times is, for example, twice. That is, if the proportion of the specified number of times to the number of times the first determination process is executed is greater than or equal to a prescribed value (e.g., 60%), the second determination unit 167 determines that the rewrite and the update of the response coefficient have been successful.

### (6.2.2) Diagnostic Method

Next, the diagnostic method of the MEMS sensor 1 according to the second variation will be described with reference to FIG. 6. Note that the flowchart shown in FIG. 6 is a mere example, and the order of the steps may accordingly be changed, or a step(s) may be omitted.

The diagnostic method of the MEMS sensor 1 according to the second variation includes a rewrite control step ST11, an update control step ST12, a generation control step ST13, the first determination step ST14, the second determination step ST16, and a notification control step ST17 as shown in FIG. 6. The rewrite control step ST11 corresponds to the rewrite control step ST1 described above, and the update control step ST12 corresponds to the update control step ST2 described above. Moreover, the generation control step ST13 corresponds to the generation control step ST3 described above, and the notification control step ST17 corresponds to the notification control step ST5 described above.

First of all, the diagnostic system 10A of the MEMS sensor 1 executes the rewrite control step ST11. In the rewrite control step ST11, the rewrite controller 161 causes, in response to the rewrite instruction from the external system 2, the storage 15 to execute the rewrite process of rewriting the response coefficient stored in the storage 15 from the first response coefficient to the second response coefficient. In other words, the storage 15 rewrites, in response to the control instruction from the rewrite controller 161, the response coefficient from the first response coefficient to the second response coefficient.

Next, the diagnostic system 10A of the MEMS sensor 1 executes the update control step ST12. In the update control step ST12, the update control unit 162 causes the circuit unit (in this variation, the digital circuit unit 14) to execute the update process of updating the response coefficient used by the digital circuit unit 14 from the first response coefficient to the second response coefficient. In other words, the digital circuit unit 14 updates, in response to the control instruction from the update control unit 162, the response coefficient from the first response coefficient to the second response coefficient.

Next, the diagnostic system 10A of the MEMS sensor 1 executes the generation control step ST13 after the update control step ST12. In the generation control step ST13, the generation controller 163 inputs a test input signal to the MEMS sensor 1 to cause the digital circuit unit 14 to generate a test output signal according to the test input signal, the test input signal being analog, the test output signal being digital. In other words, the digital circuit unit 14 generates, in response to the control instruction from the generation controller 163, a digital test output signal according to an analog test input signal input to the MEMS sensor 1.

Next, the diagnostic system 10A of the MEMS sensor 1 executes the first determination step ST14. In the first determination step ST14, the first determination unit 166 executes the first determination process of determining whether or not the test output signal from the digital circuit unit 14 is included in the allowable range specified by the test input signal.

Next, the diagnostic system 10A of the MEMS sensor 1 determines whether or not the number of times the first determination step ST14 is executed is the prescribed number of times (e.g., three times) (step ST15). If the number of times the first determination step ST14 is executed is not the prescribed number of times (step ST15: No), the diagnostic system 10A of the MEMS sensor 1 returns to the generation control step ST13. Then, the diagnostic system 10A of the MEMS sensor 1 repeats the generation control step ST13 and the first determination step ST14 until the number of times the first determination step ST14 is executed reaches the prescribed number of times. When the number of times the first determination step ST14 is executed reaches the prescribed number of times (step ST15: Yes), the diagnostic system 10A of the MEMS sensor 1 proceeds to the second determination step ST16.

Next, the diagnostic system 10A of the MEMS sensor 1 executes the second determination step ST16. In the second determination step ST16, the second determination unit 167 executes the second determination process of determining whether or not the number of times the test output signal is included in the allowable range is greater than or equal to a specified number of times. In the second determination process, if the number of times the test output signal is included in the allowable range is greater than or equal to the specified number of times, the second determination unit 167 determines that the rewrite control step ST11 and the update control step ST12 have been successful, that is, the rewrite and the update of the response coefficient have been successful. Moreover, in the second determination process, if the number of times the test output signal is included in the allowable range is less than the specified number of times, the second determination unit 167 determines that an error has occurred in the rewrite control step ST11 or the update control step ST12, that is, the rewrite or the update of the response coefficient has failed.

If the determination result by the second determination unit 167 is that the error has occurred in the rewrite control step ST11 or the update control step ST12, the diagnostic system 10A of the MEMS sensor 1 finally executes the notification control step ST17. In the notification control step ST17, the notification controller 165 outputs the control instruction to the external system 2 to cause the external system 2 to notify that the error has occurred in the rewrite control step ST11 or update control step ST12, that is, the rewrite or the update of the response coefficient has failed.

That is, in the diagnostic method of the MEMS sensor 1 according to the second variation, at a time when the rewrite control step ST11 and the update control step ST12 are executed once, the generation control step ST13 and the first determination step ST14 are executed a plurality of number of times. Then, in the diagnostic method of the MEMS sensor 1, the second determination step ST16 of determining that the rewrite and the update of the response coefficient have been successful is executed if the number of times the test output signal is included in the allowable range is greater than or equal to the specified number of times. This enables verification of whether or not the rewrite and the update of the response coefficient in the response function used by the MEMS sensor 1 have been successful

### (6.3) Other Variations

Other variations are enumerated below.

The diagnostic system 10 of the MEMS sensor 1 or a subject that executes the diagnostic method of the MEMS sensor 1 in the present disclosure includes a computer system. The computer system may include a processor and memory as principal hardware components thereof the processor executes a program stored in the memory of the computer system, thereby implementing a function as the diagnostic system 10 of the MEMS sensor 1 or the subject, which executes the diagnostic method of the MEMS sensor 1 of the present disclosure. The program may be stored in advance in the memory of the computer system. Alternatively, the program may also be downloaded over a telecommunications network or be distributed after having been recorded in some non-transitory storage medium such as a memory card, an optical disc, or a hard disk drive, any of which is readable for the computer system. The processor of the computer system includes one or a plurality of electronic circuits including semiconductor integrated circuits (IC) or large-scale integrated circuits (LSI). As used herein, the “integrated circuit” such as an IC or an LSI is called by a different name depending on the degree of integration thereof. Examples of the integrated circuits include a system LSI, a very-large-scale integrated circuit (VLSI), and an ultra-large-scale integrated circuit (ULSI). Optionally, a field-programmable gate array (FPGA) to be programmed after an LSI has been fabricated or a reconfigurable logic device allowing the connections or circuit sections inside of an LSI to be reconfigured may also be adopted as the processor. Those electronic circuits may be either integrated together on a single chip or distributed on multiple chips, whichever is appropriate. Those multiple chips may be integrated together in a single device or distributed in multiple devices without limitation. As used herein, the “computer system” includes a microcontroller including one or more processors and one or more memory elements. Thus, the microcontroller is also composed of one or more electronic circuits including a semiconductor integrated circuit or a large-scale integrated circuit.

Moreover, collecting the plurality of functions of the diagnostic system 10 of the MEMS sensor 1 in one housing is not an essential configuration of the diagnostic system 10 of the MEMS sensor 1. The components of the diagnostic system 10 of the MEMS sensor 1 may be distributed in a plurality of housings. Alternatively, at least some functions of the diagnostic system 10 of the MEMS sensor 1, for example, the function of the determination unit 164, may be implemented as a cloud computing system as well.

In the embodiment described above, the test input signal is input to the MEMS element 11, but, for example, the test input signal may be input to the analog circuit unit 12. In this case, the process time in the MEMS element 11 can be omitted, which enables the overall process time of the MEMS sensor 1 to be reduced. Note that if the responsiveness of the MEMS element 11 is poor, the test input signal has to be input to the MEMS element 11.

In the embodiment described above, the MEMS sensor 1 and the diagnostic system 10 (the rewrite controller 161, the update control unit 162, the generation controller 163, and the determination unit 164) of the MEMS sensor 1 are integrated with each other, but the MEMS sensor 1 and the diagnostic system 10 of the MEMS sensor 1 may be separated from each other. Moreover, in the embodiment described above, the entirety of the diagnostic system 10 of the MEMS sensor 1 and the MEMS sensor 1 are integrated with each other, but, for example, part (e.g., determination unit 164) of the diagnostic system 10 of the MEMS sensor 1 and the MEMS sensor 1 may be integrated with each other.

In the embodiment described above, the rewrite control step ST1, the update control step ST2, the generation control step ST3, and the determination step ST4 are executed upon activation of the MEMS sensor 1. In contrast, for example, the rewrite control step ST1, the update control step ST2, the generation control step ST3, and the determination step ST4 may be executed in response to a request from the external system 2. Thus, a diagnosis can be made at a timing preferred by the user of the MEMS sensor 1.

In the embodiment described above, the digital circuit unit 14 includes the low-pass filter 141, but the analog circuit unit 12 may include the low-pass filter, or both the analog circuit unit 12 and the digital circuit unit 14 may include low-pass filters. In sum, at least one circuit unit of the analog circuit unit 12 or the digital circuit unit 14 includes the low-pass filter.

### (Aspects)

The present specification discloses the following aspects.

A diagnostic method of a MEMS sensor (1) of a first aspect is a method of diagnosing a MEMS sensor (1) including a MEMS element (11), an analog circuit unit (12), an A/D converter (13), a digital circuit unit (14), and a storage (15). The MEMS element (11) is configured to output a first analog signal according to a magnitude of stress which is externally applied. The analog circuit unit (12) is configured to perform signal processing on the first analog signal output from the MEMS element (11) to output a second analog signal after the signal processing. The A/D converter (13) is configured to convert the second analog signal output from the analog circuit unit (12) into a digital signal. The digital circuit unit (14) is configured to generate, based on the digital signal output from the A/D converter (13), an output signal according to the magnitude of the stress to output the output signal to an external system (2). The storage (15) is configured to store a response coefficient in a response function used by at least one circuit unit of the analog circuit unit (12) or the digital circuit unit (14). The diagnostic method of the MEMS sensor (1) includes a rewrite control step (ST1; ST11), an update control step (ST2; ST12), a generation control step (ST3; ST13), and a determination step (ST4; ST14). The rewrite control step (ST1; ST11) includes causing, in response to a rewrite instruction of the response coefficient from the external system (2), the storage (15) to execute a rewrite process of rewriting the response coefficient from a first response coefficient to a second response coefficient. The update control step (ST2; ST12) includes causing the at least one circuit unit to execute an update process of updating the response coefficient from the first response coefficient to the second response coefficient. The generation control step (ST3; ST13) includes, after the update control step (ST2; ST12), causing the digital circuit unit (14) to execute a generation process of generating a test output signal according to a test input signal input to the MEMS element (11) or the analog circuit unit (12), the test output signal being digital, the test input signal being analog. The determination step (ST4; ST14) includes executing a determination process of determining whether or not the test output signal is included in an allowable range specified by the test input signal.

This aspect enables whether or not the rewrite and the update of the response coefficient in the response function used by the MEMS sensor (1) have been successful to be verified depending on whether or not the test output signal is included in the allowable range.

A diagnostic method of a MEMS sensor (1) of a second aspect referring to the first aspect further includes a notification control step (ST5). The notification control step (ST5) includes, when the test output signal is determined not to be included in the allowable range in the determination step (ST4), causing the external system (2) to execute a notification process of notifying of an occurrence of an error in the rewrite control step (ST1) or the update control step (ST2).

This aspect enables the external system (2) to notify of the occurrence of the error in the rewrite control step (ST1) or the update control step (ST2).

In a diagnostic method of a MEMS sensor (1) of a third aspect referring to any one of the first or second aspect, the rewrite control step (ST1), the update control step (ST2), the generation control step (ST3), and the determination step (ST4) are executed upon activation of the MEMS sensor (1) or in response to a request from the external system (2).

This aspect enables wrong diagnoses due to actual stress applied to the MEMS element (11) to be reduced at the time of the activation of the MEMS sensor (1). Moreover, in the case of the request from the external system (2), a diagnosis can be made at a timing preferred by a user of the MEMS sensor (1).

In a diagnostic method of a MEMS sensor (1) of a fourth aspect referring to any one of the first to third aspects, at a time when the rewrite control step (ST11) and the update control step (ST12) are executed once, the generation control step (ST13) and a first determination step (ST14) which is the determination step (ST14) are executed a plurality of number of times. The diagnostic method of the MEMS sensor (1) further includes a second determination step (ST16). The second determination step (ST16) includes, when a number of times the test output signal is included in the allowable range is greater than or equal to a specified number of times, determining that a rewrite and an update of the response coefficient have been successful.

This aspect enables wrong diagnoses due to noise or the like to be reduced.

In a diagnostic method of a MEMS sensor (1) of a fifth aspect referring to any one of the first to fourth aspects, the test input signal is an alternating current signal according to a magnitude of test stress applied to the MEMS element (11).

This aspect enables simply inputting the alternating current signal to the MEMS element (11) or the analog circuit unit (12) to verify whether or not the rewrite and the update of the response coefficient in the response function used by the MEMS sensor (1) have been successful.

In a diagnostic method of a MEMS sensor (1) of a sixth aspect referring to any one of the first to fifth aspects, the circuit unit (14) includes a low-pass filter (141).

This aspect enables the circuit unit (14) to extract a digital signal of a desired frequency range.

A diagnostic system (10) of a MEMS sensor (1) of a seventh aspect is a diagnostic system (10) for diagnosing a MEMS sensor (1) including a MEMS element (11), an analog circuit unit (12), an A/D converter (13), a digital circuit unit (14), and a storage (15). The MEMS element (11) is configured to output a first analog signal according to a magnitude of stress which is externally applied. The analog circuit unit (12) is configured to perform signal processing on the first analog signal output from the MEMS element (11) to output a second analog signal after the signal processing. The A/D converter (13) is configured to convert the second analog signal output from the analog circuit unit (12) into a digital signal. The digital circuit unit (14) is configured to generate, based on the digital signal output from the A/D converter (13), an output signal according to the magnitude of the stress to output the output signal to an external system (2). The storage (15) is configured to store a response coefficient in a response function used by at least one circuit unit of the analog circuit unit (12) or the digital circuit unit (14). The diagnostic system (10) of the MEMS sensor (1) includes a rewrite controller (161), an update control unit(162), a generation controller (163), and a determination unit (164). The rewrite controller (161) is configured to, in response to a rewrite instruction of the response coefficient from the external system (2), cause the storage (15) to execute a rewrite process of rewriting the response coefficient from a first response coefficient to a second response coefficient. The update control unit(162) is configured to cause the circuit unit (14) to execute an update process of updating the response coefficient from the first response coefficient to the second response coefficient. The generation controller (163) is configured to, after the update control unit(162) causes the circuit unit (14) to execute the update process, cause the digital circuit unit (14) to execute a generation process of generating a test output signal according to a test input signal input to the MEMS element (11) or the analog circuit unit (12), the test output signal being digital, the test input signal being analog. The determination unit (164) is configured to execute a determination process of determining whether or not the test output signal is included in an allowable range specified by the test input signal.

This aspect enables whether or not the rewrite and the update of the response coefficient in the response function used by the MEMS sensor (1) have been successful to be verified depending on whether or not the test output signal is included in the allowable range.

In a diagnostic system (10) of a MEMS sensor (1) of an eighth aspect referring to the seventh aspect, the rewrite controller (161), the update control unit(162), the generation controller (163), and the determination unit (164) are integrated with the MEMS sensor (1).

This aspect enables the entirety of the system to be downsized as compared to the case where the MEMS sensor (1) is separated from the diagnostic system (10; 10A) of the MEMS sensor (1).

The configurations of the second to sixth aspects are not essential configurations of the diagnostic method of the MEMS sensor (1) and may accordingly be omitted.

The configuration of the eighth aspect is not an essential configuration of the diagnostic system (10; 10A) of the MEMS sensor (1) and may accordingly be omitted.

### REFERENCE SIGNS LIST

1 MEMS Sensor
2 External System
10, 10A Diagnostic System
11 MEMS Element
12 Analog Circuit Unit
13 A/D Converter
14 Digital Circuit Unit
15 Storage
141 Low-Pass Filter
161 Rewrite Controller
162 Update Control Unit
163 Generation Controller
164 Determination Unit
ST1, ST11 Rewrite Control Step
ST2, ST12 Update Control Step
ST3, ST13 Generation Control Step
ST4 Determination Step
ST5, ST17 Notification Control Step
ST14 First Determination Step
ST16 Second Determination Step

1. A diagnosing method of a MEMS sensor including
a MEMS element configured to output a first analog signal according to a magnitude of stress which is externally applied,
an analog circuit unit configured to perform signal processing on the first analog signal output from the MEMS element to output a second analog signal after the signal processing,
an A/D converter configured to convert the second analog signal output from the analog circuit unit into a digital signal,
a digital circuit unit configured to generate, based on the digital signal output from the A/D converter, an output signal according to the magnitude of the stress to output the output signal to an external system, and
a storage configured to store a response coefficient in a response function used by at least one circuit unit of the analog circuit unit or the digital circuit unit, the diagnostic method comprising:
in response to a rewrite instruction of the response coefficient from the external system, causing the storage to execute a rewriting of the response coefficient from a first response coefficient to a second response coefficient;
causing the at least one circuit unit to execute an updating of the response coefficient from the first response coefficient to the second response coefficient;
after the updating of the response coefficient, causing the digital circuit unit to execute a generating of a test output signal according to a test input signal input to the MEMS element or the analog circuit unit, the test output signal being digital, the test input signal being analog; and
determining whether or not the test output signal is included in an allowable range specified by the test input signal.

2. The diagnostic method of claim 1, further comprising, when the test output signal is determined not to be included in the allowable range during the determining, causing the external system to execute a notifying of an occurrence of an error during the rewriting of the response coefficient or the updating of the response coefficient.

3. The diagnostic method of claim 1, wherein
the rewriting of the response coefficient, the updating of the response coefficient, the generating of the test output signal, and the determining are executed upon activation of the MEMS sensor or in response to a request from the external system.

4. The diagnostic method of claim 1, wherein
at a time when the rewriting of the response coefficient and the updating of the response coefficient are executed once, each of the generating of the test output signal and a first determining is executed a plurality of number of times, and
the method further comprises, when a number of times the test output signal is included in the allowable range is greater than or equal to a specified number of times, determining that a rewrite and an update of the response coefficient have been successful.

5. The diagnostic method of claim 1, wherein
the test input signal is an alternating current signal according to a magnitude of test stress applied to the MEMS element.

6. The diagnostic method of claim 1, wherein
the at least one circuit unit includes a low-pass filter.

7. A diagnostic system of a MEMS sensor including
a MEMS element configured to output a first analog signal according to a magnitude of stress which is externally applied,
an analog circuit unit configured to perform signal processing on the first analog signal output from the MEMS element to output a second analog signal after the signal processing, an A/D converter configured to convert the second analog signal output from the analog circuit unit into a digital signal,
a digital circuit unit configured to generate, based on the digital signal output from the A/D converter, an output signal according to the magnitude of the stress to output the output signal to an external system, and
a storage configured to store a response coefficient in a response function used by at least one circuit unit of the analog circuit unit or the digital circuit unit, the diagnostic system comprising:
a rewrite controller configured to, in response to a rewrite instruction of the response coefficient from the external system, cause the storage to execute a rewrite process of rewriting the response coefficient from a first response coefficient to a second response coefficient;
an update control unit configured to cause the at least one circuit unit to execute an update process of updating the response coefficient from the first response coefficient to the second response coefficient;
a generation controller configured to, after the update control unit causes the at least one circuit unit to execute the update process, causing the digital circuit unit to execute a generation process of generating a test output signal according to a test input signal input to the MEMS element or the analog circuit unit, the test output signal being digital, the test input signal being analog; and
a determination unit configured to execute a determination process of determining whether or not the test output signal is included in an allowable range specified by the test input signal.

8. The diagnostic system of claim 7, wherein
the rewrite controller, the update control unit, the generation controller, and the determination unit are integrated with the MEMS sensor.
